(19) United States
(12) Patent Application Publication
(10) Pub. No.: US 2024/0381558 A1
(43) Pub. Date: Nov. 14, 2024

(54) DISPLAY PANEL ASSEMBLY

(71) Applicant: Samsung Display Co., LTD., Yongin-si (KR)

(72) Inventor: MYUNGSUN KIM, Yongin-si (KR)

(21) Appl. No.: 18/441,317

(22) Filed: Feb. 14, 2024

(30) Foreign Application Priority Data
May 10, 2023 (KR) 10-2023-0060405

(51) Int. Cl. H05K 5/03

(52) U.S. Cl. CPC H05K 5/03

(57) ABSTRACT

Provided is a display panel assembly including a display panel including a display region, a cover panel disposed on a rear surface of the display panel and in which a through-hole overlapping the display region is defined, and a release film disposed on a rear surface of the cover panel covering the through-hole. The release film includes a first film including a front surface facing the cover panel, a second film which is disposed on the front surface of the first film, overlaps the through-hole on a plane, and has a higher light blocking property than the first film, and an adhesive film disposed between the first film and the cover panel.

### CROSS-REFERENCE TO RELATED APPLICATIONS

This application claims priority to Korean Patent Application No. 10-2023-0060405, filed on May 10, 2023, and all the benefits accruing therefrom under 35 U.S.C. § 119, the content of which in its entirety is herein incorporated by reference.

### BACKGROUND

The present disclosure herein relates to a display panel assembly, and more particularly, to a display panel assembly capable of preventing a light stain phenomenon.

A display device may provide various functions capable of organically communicating with a user by displaying an image to provide information to a user or by detecting a user's input.

A display device may include an electronic module capable of receiving an external signal or providing an output signal to the outside. In some recent display devices, an electronic module may be disposed on and assembled to a rear surface of a display panel.

### SUMMARY

The present disclosure provides a display panel assembly including a display panel with improved display characteristics.

The present disclosure also provides a display panel assembly capable of preventing a light stain phenomenon in a display panel due to external light by covering a through-hole of a cover panel with a release film having a light blocking property.

The present disclosure also provides a display panel assembly which may be implemented without (e.g., does not require) an additional light blocking member by making a release film itself have a light blocking property.

An embodiment of the inventive concept provides a display panel assembly including: a display panel including a display region; a cover panel disposed on a rear surface of the display panel and in which a through-hole overlapping the display region is defined; and a release film disposed on a rear surface of the cover panel and covering the through-hole, wherein the release film includes: a first film including a front surface facing the cover panel, a second film which is disposed on the front surface of the first film, overlaps the through-hole on a plane, and has a higher light blocking property than the first film, and an adhesive film disposed between the first film and the cover panel.

In an embodiment, at least a portion of the adhesive film may be disposed between the first film and the second film.

In an embodiment, the second film may be in contact with the rear surface of the cover panel.

In an embodiment, on a cross section perpendicular to the rear surface of the cover panel, a length of a contact portion between the second film and the cover panel may be about 0.5 mm or more.

In an embodiment, a color of the second film may include a black color.

In an embodiment, the cover panel may include a first cover portion in contact with the adhesive film and a second cover portion in contact with the second film, and in a thickness direction of the cover panel, a first thickness of the first cover portion may be greater than or equal to a second thickness of the second cover portion.

In an embodiment, the first film may be transparent.

In an embodiment, the release film may further include a third film in contact with the front surface of the first film, the first film may include a first portion overlapping the cover panel on a plane and a second portion spaced apart from the cover panel on the plane, the second film overlaps the first portion and is spaced apart from the second portion on the plane, and the third film may overlap the second portion and may be spaced apart from the first portion on the plane.

In an embodiment, a color of the second film is different from a color of the third film.

In an embodiment, the display panel may include a non-display region adjacent to the display region, and the second film may be spaced apart from the non-display region on a plane.

In an embodiment, the display panel assembly may further include a circuit board disposed between the cover panel and the display panel.

In an embodiment, the second film may be in direct contact with the first film.

In an embodiment, the through-hole and the second film may each be provided in plurality, and the plurality of second films may respectively cover the plurality of through-holes.

In an embodiment, on a cross section perpendicular to a normal direction of a rear surface of the cover panel, the through-holes may be of different planar shapes.

In an embodiment of the inventive concept, a display panel assembly includes: a display panel including a display region; a cover panel disposed on a rear surface of the display panel and in which a through-hole overlapping the display region is defined; and a release film disposed on a rear surface of the cover panel and covering the through-hole, wherein the release film includes: a first film including a front surface facing the cover panel, and a second film which is disposed on the front surface of the first film, overlaps the through-hole and the cover panel on a plane, and has a higher light blocking property than the first film.

In an embodiment, the release film may further include an adhesive film disposed between the first film and the cover panel, and at least a portion of the adhesive film may be disposed between the first film and the second film.

In an embodiment, the second film may be in contact with the rear surface of the cover panel, and on a cross section perpendicular to the rear surface of the cover panel, a length of a contact portion between the second film and the cover panel may be about 0.5 mm or more.

In an embodiment, the cover panel may include a first cover portion in contact with the adhesive film and a second cover portion in contact with the second film, and in a thickness direction of the cover panel, a first thickness of the first cover portion may be greater than or equal to a second thickness of the second cover portion.

In an embodiment, the first film may be transparent, and a color of the second film may include a black color.

In an embodiment, the release film may further include a third film in contact with the front surface of the first film, the first film may include a first portion overlapping the cover panel on a plane and a second portion spaced apart from the cover panel on a plane, the second film may overlap the first portion and is spaced apart from the second portion on a plane, and the third film may overlap the second portion and be spaced apart from the first portion on a plane.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is an exploded perspective view of an embodiment of a display panel assembly in accordance with example aspects of the present disclosure;

FIG. 2 is a plan view of a partial configuration of an embodiment of a display panel assembly in accordance with example aspects of the present disclosure;

FIG. 3 is a plan view of a partial configuration of an embodiment of a display panel assembly in accordance with example aspects of the present disclosure;

FIGS. 4A to 4C are cross-sectional views of a partial configuration of an embodiment of a display panel assembly in accordance with example aspects of the present disclosure;

FIG. 5 is an enlarged view of an embodiment of a cover panel in accordance with example aspects of the present disclosure; and

FIG. 6 is a plan view of a partial configuration of an embodiment of a display panel in accordance with example aspects of the present disclosure.

### DETAILED DESCRIPTION

In this specification, it will be understood that when an element (or a region, a layer, a portion, or the like) is referred to as “being on”, “connected to” or “coupled to” another element, it may be directly disposed on/connected/coupled to the other element, or intervening elements may be disposed therebetween.

Like reference numerals or symbols refer to like elements throughout. In the drawings, the thickness, the ratio, and the dimension of the elements are exaggerated for effective description of the technical contents. The term “and/or” includes all combinations of one or more of the associated listed elements.

Although the terms first, second, etc. may be used to describe various elements, these elements should not be limited by these terms. In the examples described herein, these terms are used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

The terms such as “below”, “lower”, “above”, “upper” and the like, may be used herein for the description to describe one element's relationship to another element illustrated in the figures. It will be understood that the terms have a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

A display panel and a method of manufacturing the same in accordance with example aspects of the present disclosure are described herein with reference to the accompanying drawings.

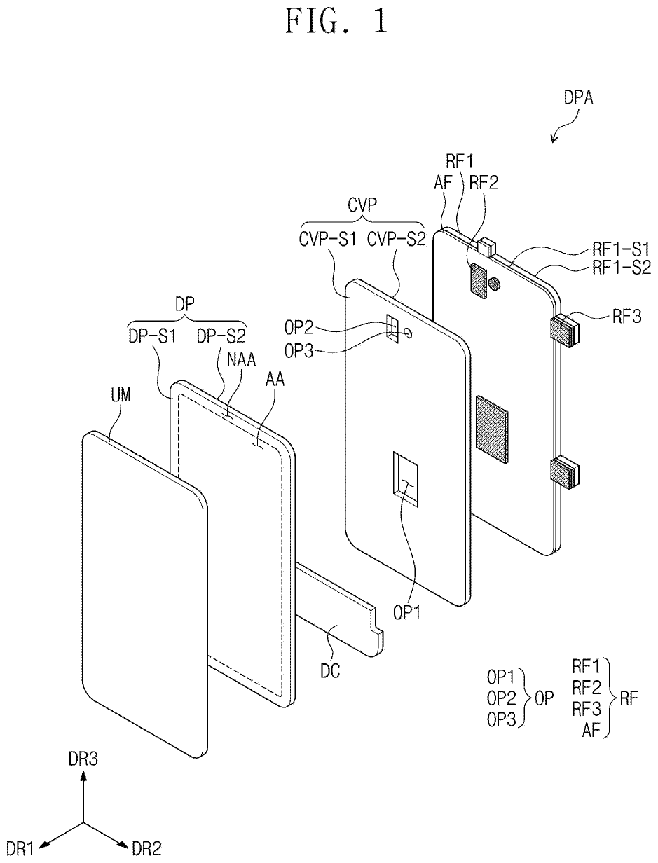

FIG. 1 is an exploded perspective view of an embodiment of a display panel assembly in accordance with example aspects of the present disclosure.

Referring to FIG. 1, a display panel assembly DPA according to an embodiment may include a display panel DP, a cover panel CVP, a circuit board DC, an upper member UM, and a release film RF.

The display panel DP may include a display region AA and a peripheral region NAA. The display region AA may be a region in which the display panel DP is capable of displaying an image is displayed and sensing an external input. The display region AA may be a region which is activated in response to an electrical signal. The display region AA is a region in which an image may be displayed and various forms of external inputs may be sensed. The external inputs may include various forms of inputs applied from the outside of a display device. For example, the external inputs may include, in addition and/or alternative to an external input by a part of the user's body (e.g., a user's hand), an external input (for example, hovering) applied while approaching or being adjacent within a predetermined distance to an electronic device. In some aspects, the external inputs may have various forms such as, for example, force, pressure and light, but is not limited to any one embodiment.

The peripheral region NAA may be adjacent to the display region AA. The peripheral region NAA may be a region in which a driving circuit for driving pixels of the display region AA and lines connected thereto are disposed, and lines connected to sensing electrodes for sensing external inputs are further disposed in the peripheral region NAA.

The cover panel CVP may support the display panel DP. The cover panel CVP may include a front surface CVP-S1 facing a rear surface DP-S2 of the display panel DP and a rear surface CVP-S2 opposed to the front surface CVP-S1.

In the example embodiment, the cover panel CVP is illustrated as having a single layer, but embodiments supported by the present disclosure are not limited thereto. The cover panel CVP may have a stacked structure of a plurality of layers. For example, the cover panel CVP may have a cushion layer, a support layer, and an adhesive layer. The cushion layer may protect the display panel DP and an electronic module against physical impacts applied from the outside of the display device. The support layer may be a support substrate which supports members included in the display device including the display panel DP, and have functions such as, for example, heat radiation and electromagnetic wave shielding. The adhesive layer may be bonded to each of a plurality of layers (e.g., cushion layer, support layer) to fix the positions between the layers. In this case, the front surface CVP-S1 may be defined by one layer among the cushion layer, the support layer, and the adhesive layer, and the rear surface CVP-S2 may be defined by another layer among the cushion layer, the support layer, and the adhesive layer.

The cover panel CVP in accordance with embodiments of the present disclosure may have various structures in which the cover panel CVP covers the rear surface DP-S2 of the display panel DP, and is not limited to any one embodiment.

According to an embodiment, the rear surface CVP-S2 of the cover panel CVP may have conductivity. For example, the rear surface CVP-S2 of the cover panel CVP may include copper (Cu) or aluminum (Al). In some embodiments, the rear surface CVP-S2 of the cover panel CVP may be a non-flat surface. For example, the cover panel CVP may include embossing.

The cover panel CVP may include one or more through-holes OP defined therein. The through-holes OP may be defined as passing through a front surface and a rear surface of the cover panel CVP. The through-holes OP of the cover panel CVP may be defined at a position overlapping the display region AA on a plane. That is, the through-holes OP of the cover panel CVP may be spaced apart from the peripheral region NAA and be formed within the display region AA on a plane defined by a second direction DR2 and a third direction DR3.

As illustrated at FIG. 1, the through-hole OP defined in the cover panel CVP may have a polygonal shape (e.g., referring to through-hole OP1 or through-hole OP2), on a plane defined by the second direction DR2 and the third direction DR3, and/or may have a circular shape on the plane (e.g., referring to through-hole OP3).

The through-hole OP may be provided in plurality. For example, the cover panel CVP may include a plurality of through-holes OP1, OP2, and OP3 defined therein and spaced apart from each other. On a cross section in a direction perpendicular to the third direction DR3 and in a direction perpendicular to a normal direction of the rear surface CVP-S2 of the cover panel CVP, respective planar shapes of the through-holes OP1, OP2, and OP3 are illustrated to be different from each other, but embodiments supported by the present disclosure are not limited thereto. For example, two or more (or all) of through-holes OP1, OP2, and OP3 may be of the same shape.

An electronic module may be accommodated in each of the through-holes OP1, OP2, and OP3. The example descriptions provided herein with reference to a given through-hole OP (e.g., through-hole OP1) of the cover panel CVP may be similarly applied to other through-holes OP (e.g., through-hole OP2, through-hole OP3) described herein. In some aspects, for a given through-hole OP in which an electronic module is accommodated, the electronic module may overlap the through-hole OP. The electronic module may receive an external input applied via the through-hole OP of the cover panel CVP or provide an output via the through-hole OP of the cover panel CVP. In an embodiment, the electronic module may include various electronic devices such as, for example, a sensor, a camera, and a speaker. The sensor may be provided as various examples such as an optical sensor for fingerprint identification, an illuminance sensor, and a proximity sensor. Electronic modules different from each other may be disposed in the respective through-holes, or the same electronic module provided in plurality may be provided in the respective through-holes. However, the electronic modules are not limited to any one embodiment.

The circuit board DC may be disposed between the display panel DP and the cover panel CVP. The circuit board DC may be connected to the display panel DP. The circuit board may be flexible. Accordingly, when being accommodated in the display panel DP and a housing of the cover panel CVP, the circuit board may be folded and accommodated on the rear surface side (rear surface DP-S2) of the display panel. However, the properties of the circuit board and the accommodation of the circuit board in the display panel DP described herein are examples, and aspects of the present disclosure are not limited thereto. For example, the circuit board may be rigid and is not limited to any one embodiment.

The release film RF may face the cover panel CVP in the first direction DR1. The release film RF may include a first film RF1, a second film RF2, an adhesive film AF, and a third film RF3.

A front surface RF1-S1 of the first film RF1 may face the rear surface CVP-S2 of the cover panel CVP in the first direction DR1, and a rear surface RF1-S2 of the first film RF1 may face the front surface RF1-S1 of the first film RF1. The first film RF1 may have higher transmittance than the later-described second film RF2. For example, the first film RF1 may be transparent. However, embodiments supported by the present disclosure are not limited thereto. The first film RF1 may be translucent, and is not limited to any one embodiment.

A portion of the first film RF1 may overlap the cover panel CVP on a plane (e.g., a plane defined by second direction DR2 and third direction DR3), and another portion of the first film RF1 may not overlap the cover panel CVP on a plane (e.g., the plane defined by second direction DR2 and third direction DR3). The second film RF2 may be disposed on the front surface RF1-S1 of the first film RF1. The second film RF2 may overlap a region, of the first film RF1, overlapping the cover panel CVP.

The second film RF2 may be disposed at respective positions overlapping through-holes OP on a plane (e.g., the plane defined by second direction DR2 and third direction DR3). Portions of the second film RF2 may cover the through-holes OP, and another portion of the second film RF2 may cover (not illustrated) the rear surface CVP-S2 of the cover panel CVP. The second film RF2 may have a higher light blocking property than the first film RF1. The second film RF2 may include a light blocking material, and for example, the second film RF2 may include a black color. However, embodiments supported by the present disclosure are not limited thereto. For example, the second film RF2 may include any suitable color (e.g., a blue color) different from that of the second film RF2 and supportive of aspects of the display panel assembly DPA described herein, and is not limited to any one embodiment.

When the display panel assembly DPA is assembled, some of external light may pass through the first film RF1 and reach the cover panel CVP. Since the display panel assembly DPA according to the example embodiments described herein further includes the second film RF2 overlapping the through-holes OP, light may be blocked from passing through the through-holes OP. Accordingly, for example, the second film RF2 may block external light passing through the first film RF1 from reaching the display panel DP through the through-hole OP. Therefore, for example, the second film RF2 may prevent the display panel DP from being exposed to light incident from the rear surface, and light stain caused by light exposure may be prevented from occurring in the display panel DP.

As described herein, the through-hole OP may be provided in plurality. The second film RF2 may be provided in plurality. A plurality of second films RF2 may respectively cover the through-holes OP. Accordingly, for example, the respective application of the second films RF2 to cover the through-holes OP may effectively prevent (e.g., easily, with reduced complexity) exposure of the through-holes OP to external light. In some aspects, regardless of the positions of the through-holes OP, the respective application of the second films RF2 to cover the through-holes OP may effectively block light from passing through the individual through-holes OP. However, in some alternative and/or additional embodiments in which some of the through-holes OP are to be exposed, some of the through-holes OP exposing the display panel DP may be spaced apart from the second film RF2 on a plane (e.g., the plane defined based on second direction DR2 and third direction DR3), and the arrangement of the through-holes OP is not limited to any one embodiment. In an example, a through-hole OP may be spaced apart from the second film RF2 in the second direction DR2 or the third direction DR3 such that at least a portion of the through-hole OP is not overlapped by the second film RF2.

The adhesive film AF may be disposed between the cover panel CVP and the first film RF1. At least a portion of the adhesive film AF may be disposed between the first film RF1 and the second film RF2. A portion of the adhesive film AF overlapping the second film RF2 may be spaced apart from the cover panel CVP with the second film RF2 therebetween, and a portion of the adhesive film AF not overlapping the second film RF2 may be in contact with the cover panel CVP. That is, a portion of the adhesive film AF may be in contact with each of the first film RF1 and the second film RF2, and another portion of the adhesive film may be in contact with each of the first film RF1 and the cover panel CVP.

A shape of the adhesive film AF may correspond to a shape of the first film RF1. That is, the adhesive film AF may completely overlap the first film RF1 on a plane (e.g., the plane defined based on second direction DR2 and third direction DR3). However, embodiments supported by the present disclosure are not limited thereto. The adhesive film AF may partially overlap the first film RF1 on a plane (e.g., the plane defined based on second direction DR2 and third direction DR3), but is not limited to any one embodiment.

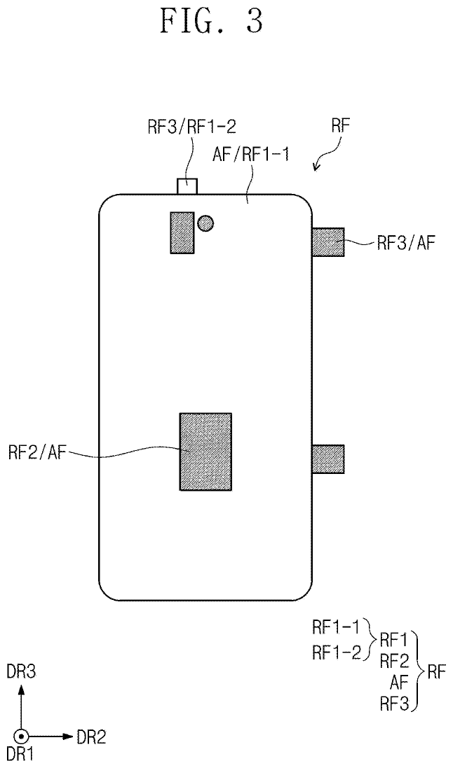

The third film RF3 may be disposed on the front surface RF1-S1 of the first film RF1. The third film RF3 may overlap a later-described second portion RF1-2 (see FIG. 3) on a plane (e.g., the plane defined based on second direction DR2 and third direction DR3). The third film RF3 may be spaced apart from the second portion RF1-2 (see FIG. 3) with the adhesive film AF therebetween.

The third film RF3 may serve as a tap or marker based on which a condition of the display panel assembly DPA may be determined, example aspects of which are later described herein. The third film RF3 may include a light blocking material such as, for example, the light blocking material described with reference to the second film RF2, and a portion or the entirety of the third film RF3 may be of the same color as the second film RF2. However, embodiments supported by the present disclosure are not limited thereto. For example, the third film RF3 may be implemented such that the third film RF3 is absent a light blocking material, and is not limited to any one embodiment.

The display panel assembly DPA may include an upper member UM. The upper member UM may face the front surface DP-S1 of the display panel DP in the first direction DR1. The upper member UM may cover the front surface DP-S1 of the display panel DP, and for example, the upper member UM may include a support member or a window. In an example, the upper member UM may completely overlap the front surface DP-S1 of the display panel DP with respect to a plane (e.g., the plane defined based on second direction DR2 and third direction DR3).

However, embodiments of the upper member UM are not limited to the examples described herein. For example, the upper member UM may further include a polarizing member in addition to a window, and is not limited to any one embodiment. For example, the polarizing member of the upper member UM may include a polarizing plate and may function to reduce a reflection phenomenon caused by external light.

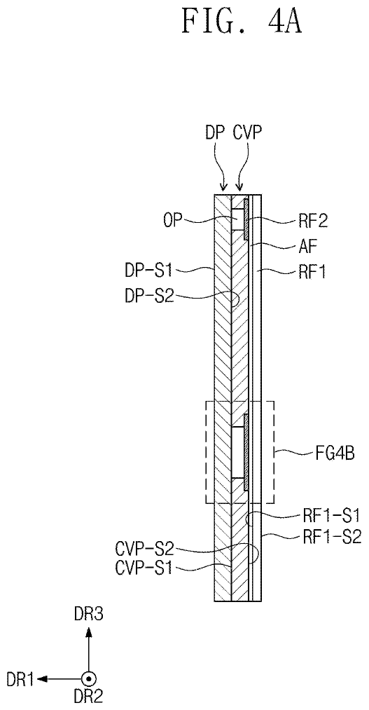

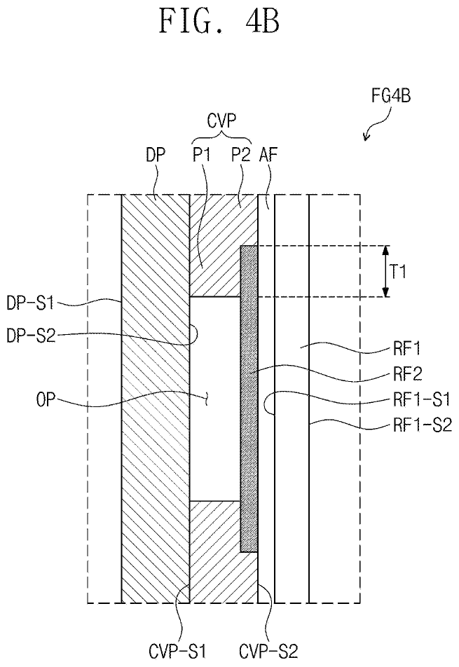

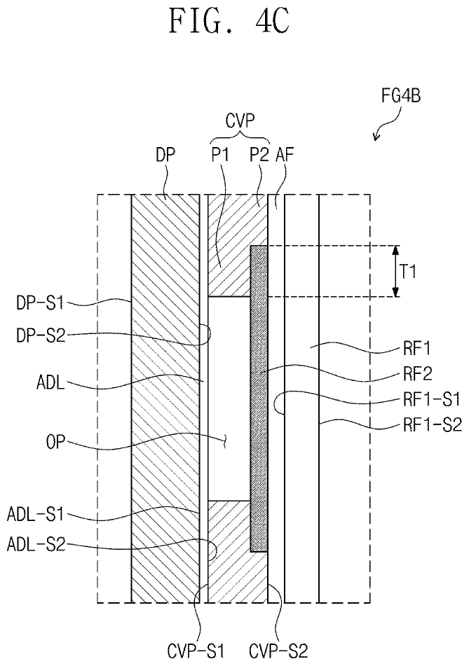

In the example of FIG. 1, a component of an additional adhesive member between the cover panel CVP and the display panel DP is omitted, but embodiments supported by the present disclosure are not limited thereto. For example, an adhesive member such as, for example, an adhesive layer ADL (see FIG. 4C) may be provided between the cover panel CVP and the display panel DP may be provided, and is not limited to any one embodiment.

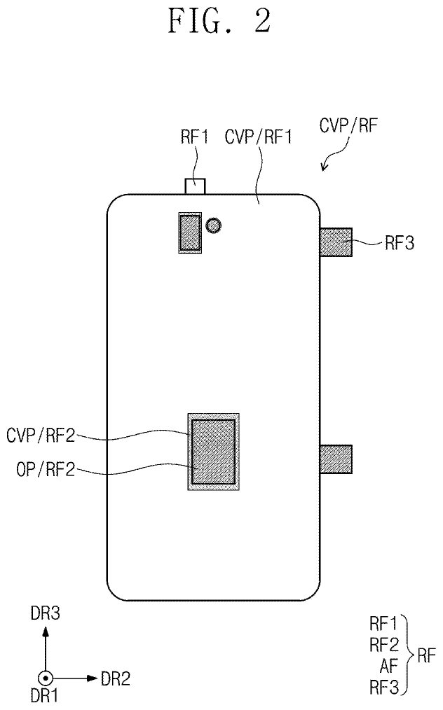

FIGS. 2 and 3 are plan views of a partial configuration of an embodiment of a display panel assembly in accordance with example aspects of the present disclosure. Specifically, FIG. 2 is a plan view of a state in which a cover panel CVP overlaps a release film RF, when viewed in the first direction DR1, and FIG. 3 is a plan view of a state in which components of the release films RF are overlapping, when viewed in the first direction DR1.

The release film RF may overlap the cover panel CVP in the first direction DR1. As described herein, the adhesive film AF may have the same shape as a first film RF1 and completely overlap the first film RF1 on a plane (e.g., the plane defined based on second direction DR2 and third direction DR3). For convenience of description, descriptions of the adhesive film AF with reference to FIG. 2 are omitted for brevity.

Referring to FIG. 2, at least a portion of the cover panel CVP may overlap the first film RF1 on a plane (e.g., the plane defined based on second direction DR2 and third direction DR3). In some aspects, a portion, of the first film RF1, overlapping the cover panel CVP and a through-hole OP may overlap a second film RF2. A portion, of the first film RF1, not overlapping the cover panel CVP may overlap a third film RF3.

A portion, of the first film RF1, overlapping the cover panel CVP may be a first portion RF1-1 (see FIG. 3) to be described later herein. A portion, of the first film RF1, not overlapping the cover panel CVP may be a second portion RF1-2 (see FIG. 3) to be described later.

A portion of the second film RF2 may overlap the through-hole OP. Another portion of the second film RF2 may overlap the cover panel CVP. A portion of the second film RF2 overlapping the through-hole OP may be adjacent to a portion of the second film RF2 overlapping the cover panel CVP. In some aspects, a portion where the second film RF2 does not overlap the cover panel CVP may be adjacent to a portion where the second film RF2 overlaps the cover panel CVP. Expressed another way, a portion of the cover panel CVP not overlapped by the second film RF2 may be adjacent to a portion of the cover panel CVP which is overlapped by the second film RF2.

With reference to the cover panel CVP, a portion of the cover panel CVP overlapped by the second film RF2 may be referred to as a later-described first cover portion P1 (see FIG. 4B) of the cover panel CVP. In some aspects, a portion of the cover panel CVP not overlapped by the second film RF2 may be referred to as a later-described second cover portion P2 (see FIG. 4B) of the cover panel CVP.

The second film RF2 may be provided in plurality. A plurality of second films RF2 may respectively have different shapes. For example, the plurality of second films RF2 may have substantially the same shapes as the respective through-holes OP that the second films RF2 overlap, but embodiments supported by the present disclosure are not limited thereto. The second films RF2 may have various shapes. It is to be understood that the plurality of second films RF2 may refer to portions of the same film (e.g., second film RF2), disposed at different locations with respect to a plane (e.g., the plane defined based on second direction DR2 and third direction DR3).

Referring to FIG. 3, components of a release film RF may overlap each other in the first direction DR1. In some examples, the components of release film RF may include a first film RF1, a second film RF2, and a third film RF3 described herein.

The first film RF1 may include a first portion RF1-1 and a second portion RF1-2. The first portion RF1-1 overlaps the cover panel CVP on a plane (e.g., the plane defined based on second direction DR2 and third direction DR3), and the second portion RF1-2 does not overlap the cover panel. In some aspects, the first portion RF1-1 may overlap the second film RF2 on a plane (e.g., the plane defined based on second direction DR2 and third direction DR3), for example, at locations corresponding to through-holes OP. In some aspects, the second portion RF1-2 may overlap the third film RF3.

The first portion RF1-1 may overlap the adhesive film AF. A portion of the second portion RF1-2 may not overlap the adhesive film AF, and another portion of the second portion RF1-2 may overlap the adhesive film AF. A portion, of the second portion RF1-2, overlapping the adhesive film AF may overlap the third film RF3.

The second film RF2 may overlap the adhesive film AF. In some aspects, the second film RF2 may overlap the first portion RF1-1. In some aspects, the second film RF2 may not overlap the third film RF3 on a plane (e.g., the plane defined based on second direction DR2 and third direction DR3).

The third film RF3 may overlap the adhesive film AF. In some aspects, the third film RF3 may overlap the second portion RF1-2.

FIGS. 4A to 4C are cross-sectional views of a partial configuration of a display panel assembly in accordance with example aspects of the present disclosure. Specifically, FIG. 4B is an enlarged view of FG4B of FIG. 4A, and FIG. 4C is an enlarged view illustrating a portion of a display panel assembly in a state in which an adhesive layer is further provided at the display panel assembly of FIG. 4A.

Referring to FIG. 4A, a display panel DP, a cover panel CVP, and a release film RF may be sequentially disposed along the first direction DR1. A rear surface DP-S2 of the display panel DP may face a front surface CVP-S1 of the cover panel CVP, a rear surface CVP-S2 of the cover panel CVP may face an adhesive film AF or a second film RF2, the second film RF2 may face the adhesive film AF (e.g., a rear surface of the second film RF2 may face a front surface of the adhesive film AF), and the adhesive film AF may face a first film RF1 (e.g., a rear surface of the adhesive film AF may face a front surface of the first film RF1).

The first film RF1 may be spaced apart from the cover panel CVP, with the second film RF2 or the adhesive film AF between the first film RF1 and the cover panel CVP.

The adhesive film AF may be disposed between the first film RF1 and the second film RF2 and be in contact with each of the first film RF1 and the second film RF2. In some aspects, a portion of the adhesive film AF may be spaced apart from the cover panel CVP, with the second film RF2 between the portion of the adhesive film AF and the cover panel CVP, and another portion of the adhesive film AF may be in contact with the cover panel CVP.

The second film RF2 may overlap a through-hole OP of the cover panel CVP and one or more portions of the cover panel CVP. That is, the second film RF2 may cover at least a portion of the cover panel CVP and the through-hole OP. For example, the second film RF2 may fully cover the through-hole OP and cover at least a portion of the rear surface CVP-S2 of the cover panel CVP.

Since the second film RF2 has a higher light blocking property than the first film RF1, light passing through the first film RF1 may be prevented by the second film RF2 from propagating toward the through-hole OP in the first direction DR1 or a direction crossing the first direction DR1. The second film RF2 may prevent portions of the display panel DP overlapping the through-hole OP and regions adjacent thereto from being exposed to light, and thus light stain caused by light exposure may be prevented from occurring in the display panel DP.

Referring to FIG. 4B, the cover panel CVP may include a first cover portion P1 and a second cover portion P2. The first cover portion P1 of the cover panel CVP may at least partially overlap the second film RF2, and the second cover portion P2 of the cover panel CVP may at least partially overlap the adhesive film AF and the first film RF1. In some aspects, the first cover portion P1 may be in contact with the second film RF2, and the second cover portion P2 may be in contact with the adhesive film AF.

On a cross section perpendicular to the rear surface CVP-S2 of the cover panel CVP, the length Tl of an overlapping region between the first cover portion P1 and the second film RF2 may be about 1 mm or more. In some aspects, the length Tl of the overlapping region between the first cover portion P1 and the second film RF2 may be about 0.5 mm or more. In some aspects, as the first cover portion P1 of the cover panel CVP may overlap the second film RF2 by about 0.5 mm or more, and the overlap may prevent light from passing through the first film RF1 and the second film RF2 to propagate toward the through-hole OP. The overlap between the cover panel CVP and the second film RF2 may be referred to as a contact portion between the second film RF and the cover panel CVP. On a cross section perpendicular to the rear surface of the cover panel, a length of a contact portion between the second film and the cover panel is about 0.5 mm or more.

In some aspects, since the length Tl of the overlapping region between the first cover portion P1 and the second film RF2 may be about 0.5 mm or more, the overlap may prevent concentration of external forces on a region adjacent to the through-hole OP of the cover panel CVP during attachment of the release film RF to the cover panel CVP, and thus to prevent damage to the through-hole OP. That is, for example, since the length Tl of the overlapping region between the first cover portion P1 and the second film RF2 is about 0.5 mm or more, the overlap may prevent concentration of external forces on a region adjacent to the through-hole OP of the cover panel CVP during contact of the cover panel CVP with the release film RF, which may uniformly maintain the quality of the display panel assembly DPA and the quality of a display device to be manufactured later.

The drawings each illustrate examples of the length Tl of the overlapping region between the cover panel CVP and the second film RF2 along the third direction DR3, and embodiments of the inventive concept are not limited to the examples illustrated in the drawings. For example, a length of the overlapping region between the cover panel CVP and the second film RF2 along the second direction DR2 may be about 0.5 mm or more. In another example, respective lengths of the overlapping region between the cover panel CVP and the second film RF2 along the second direction DR2 and the third direction DR3 may each be about 0.5 mm or more. The lengths of the overlapping regions are not limited to any one embodiment.

Referring to FIG. 4C, the display panel assembly DPA may further include an adhesive layer ADL. The adhesive layer ADL may be disposed between the display panel DP and the cover panel CVP.

Specifically, for example, a front surface ADL-S1 of the adhesive layer ADL may be in contact with the rear surface DP-S2 of the display panel DP, and a rear surface ADL-S2 of the adhesive layer ADL may be in contact with the front surface CVP-S1 of the cover panel CVP. Since the adhesive layer ADL is disposed between the rear surface DP-S2 of the display panel DP and the front surface CVP-S1 of the cover panel CVP, and the cover panel CVP and the display panel DP are spaced apart from each other due to the adhesive layer ADL, the example configuration prevents a gap from occurring between the cover panel CVP and the display panel DP and supports increased uniformity in thickness and improved quality of the display panel assembly DPA.

Also, as described herein, since the second film RF2 may cover the through-hole OP and at least a portion of the second film RF2 may overlap the cover panel CVP, the adhesive layer ADL may be substantially aligned along the third direction DR3. That is, the adhesive layer ADL may maintain a preset thickness between the display panel DP and the cover panel CVP in the first direction DR1.

The drawings provided herein illustrate an example case where the adhesive layer ADL overlaps the through-hole OP, but embodiments supported by the present disclosure are not limited thereto. For example, the adhesive layer ADL may be disposed such that the adhesive layer ADL does not overlap (or partially overlaps) the through-hole OP, and is not limited to any one embodiment.

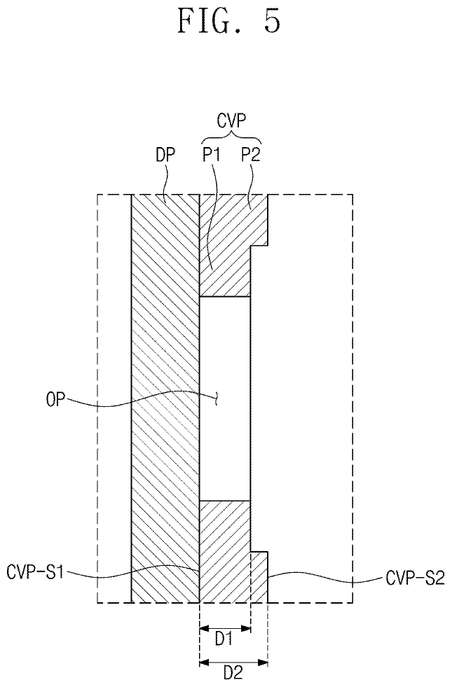

FIG. 5 is an enlarged view of a cover panel in accordance with example aspects of the present disclosure.

Referring to FIG. 5, a cover panel CVP may include a first cover portion P1 and a second cover portion P2. The first cover portion P1 of the cover panel CVP may be a portion in contact with the above-described second film RF2 (see FIG. 4B), and the second cover portion P2 of the cover panel CVP may be a portion in contact with the above-described adhesive film AF (see FIG. 4B). However, embodiments supported by the present disclosure are not limited thereto, and a portion of the first cover portion P1 may be a portion in contact with the adhesive film AF (see FIG. 4B). So as not to distract from the features described with reference to FIG. 5, the adhesive film AF and the release film RF are not illustrated/labeled.

The respective thicknesses of the first cover portion P1 and the second cover portion P2 of the cover panel CVP may be different from each other. For example, a stepped portion may be defined between the first cover portion P1 and the second cover portion P2. Specifically, for example, the first thickness D1 of the first cover portion P1 may be smaller than or equal to the second thickness D2 of the second cover portion P2. In some embodiments, the first thickness D1 of a portion (e.g., first cover portion P1) in contact with the second film RF2 may be smaller than the second thickness D2 of a portion (e.g., second cover portion P2) in contact with the adhesive film AF (see FIG. 4B), and therefore, when the second film RF2 described herein is attached to the cover panel CVP, the second film RF2 may be in contact with the first cover portion P1. In an example, the second film RF2 may overlap the first cover portion P1 and may not overlap the second cover portion P2, on a plane crossing the thickness direction of the cover panel CVP (e.g., the plane defined based on second direction DR2 and third direction DR3).

Accordingly, the features described herein in accordance with example aspects of the present disclosure may prevent an occurrence of a gap between the display panel DP and the cover panel CVP due to the formation of an empty space between the display panel DP and the cover panel CVP when the cover panel CVP is attached to the display panel DP. Also, when the release film RF is attached to the cover panel CVP, the feature described herein may prevent an occurrence of a gap between the first film RF1 (see FIG. 4B) and the cover panel CVP. In other words, a contact surface between the display panel DP and the cover panel CVP may be formed uniformly. Therefore, the features described herein support increased uniformity in thickness and improved quality of the display panel assembly DPA.

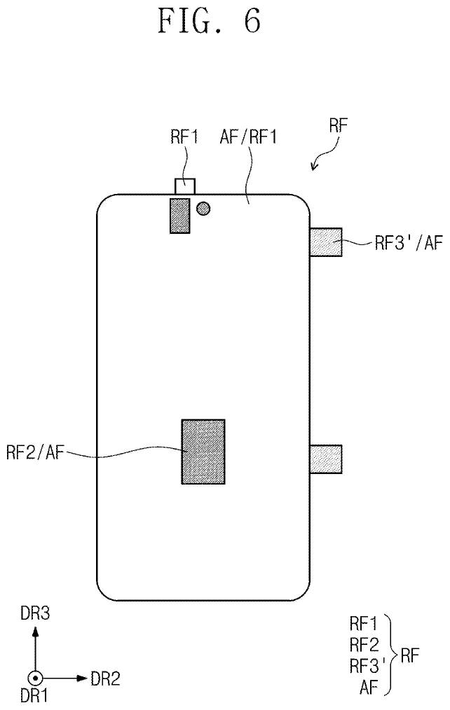

FIG. 6 is a plan view of a partial configuration of a display panel assembly in accordance with example aspects of the present disclosure.

Referring to FIG. 6, a third film RF3′ of a display panel assembly DPA in accordance with example aspects of the present disclosure may include a color different from that of the second film RF2. For example, when the second film RF2 includes a black color, the third film RF3′ may include a red color. However, embodiments supported by the present disclosure are not limited thereto, and the third film RF3′ may include any suitable color (e.g., a blue color) different from that of the second film RF2 and supportive of aspects of the display panel assembly DPA described herein.

In accordance with example aspects of the present disclosure, the second film RF2 and the third film RF3′ may respectively have different colors, and therefore a portion, of the display panel assembly DPA, which is to be subjected to quality inspection, may be easily specified as the second film RF2 portion. Therefore, a waiting time (e.g., inspection time), a facility alignment time, and the like of the display panel assembly DPA for quality inspection may be reduced.

A portion of the third film RF3′ may function as a tap or marker based on which a condition of the display panel assembly DPA may be determined. For example, after performing quality inspection on the display panel assembly DPA, a color of the third film RF3′ may vary according to a condition of the display panel assembly DPA. That the colors are pre-set colors match with the conditions of the display panel assembly DPA. Accordingly, the third film RF3′ may be selected to have a predetermined color (e.g., a color recognizable by a user), such that a condition of the display panel assembly DPA may be visually determined. Since the condition of the display panel assembly DPA may be visually determined due to color of the third film RF3′, it is possible to easily distinguish between a display panel assembly DPA required to be subjected to quality inspection, a display panel assembly DPA required to be subjected to a following process, and a display panel assembly DPA required to be subjected to an additional process, and thus a waiting time for a subsequent process may be reduced.

Accordingly, for example, by making the colors of the second film RF2 and the third film RF3′ differ from each other, it is possible to increase an output and production efficiency of a display module and a display device, and thus to reduce process costs.

A display panel assembly in accordance with example aspects of the present disclosure may provide a display panel with improved display characteristics.

A display panel assembly in accordance with example aspects of the present disclosure may prevent a light stain phenomenon in a display panel due to external light, by covering a through-hole of a cover panel with a release film having a light blocking property.

A display panel assembly in accordance with example aspects of the present disclosure may be implemented without an additional light blocking member by making a release film have a light blocking property, thereby reducing manufacturing and processing costs.

Although example embodiments of the inventive concept have been described, it is to be understood that the inventive concept should not be limited to these embodiments, and various changes and modifications can be made by one of ordinary skill in the art within the spirit and scope of the inventive concept as claimed herein. Therefore, the technical scope of the inventive concept is not limited to the contents described in the detailed description of the specification, but should be determined by the claims.

What is claimed is:

1. A display panel assembly comprising:
a display panel including a display region;
a cover panel disposed on a rear surface of the display panel and in which a through-hole overlapping the display region is defined; and
a release film disposed on a rear surface of the cover panel and covering the through-hole,
wherein the release film comprises:
a first film including a front surface facing the cover panel;
a second film which is disposed on the front surface of the first film, overlaps the through-hole on a plane, and has a higher light blocking property than the first film; and
an adhesive film disposed between the first film and the cover panel.

2. The display panel assembly of claim 1, wherein at least a portion of the adhesive film is disposed between the first film and the second film.

3. The display panel assembly of claim 1, wherein the second film is in contact with the rear surface of the cover panel.

4. The display panel assembly of claim 3, wherein on a cross section perpendicular to the rear surface of the cover panel, a length of a contact portion between the second film and the cover panel is about 0.5 mm or more.

5. The display panel assembly of claim 1, wherein a color of the second film comprises a black color.

6. The display panel assembly of claim 1, wherein the cover panel comprises a first cover portion in contact with the adhesive film and a second cover portion in contact with the second film, and
in a thickness direction of the cover panel, a first thickness of the first cover portion is greater than or equal to a second thickness of the second cover portion.

7. The display panel assembly of claim 1, wherein the first film is transparent.

8. The display panel assembly of claim 1, wherein the release film further comprises a third film in contact with the front surface of the first film,
the first film comprises a first portion overlapping the cover panel on a plane and a second portion spaced apart from the cover panel on the plane,
the second film overlaps the first portion and is spaced apart from the second portion on the plane, and
the third film overlaps the second portion and is spaced apart from the first portion on the plane.

9. The display panel assembly of claim 8, wherein a color of the second film is different from a color of the third film.

10. The display panel assembly of claim 1, wherein the display panel comprises a non-display region adjacent to the display region, and
the second film is spaced apart from the non-display region on a plane.

11. The display panel assembly of claim 1, further comprising a circuit board disposed between the cover panel and the display panel.

12. The display panel assembly of claim 1, wherein the second film is in direct contact with the first film.

13. The display panel assembly of claim 1, wherein the through-hole and the second film are each provided in plurality, and
the plurality of second films respectively cover the plurality of through-holes.

14. The display panel assembly of claim 13, wherein on a cross section perpendicular to a normal direction of a rear surface of the cover panel, the through-holes are of different planar shapes.

15. A display panel assembly comprising:
a display panel including a display region;
a cover panel disposed on a rear surface of the display panel and in which a through-hole overlapping the display region is defined; and
a release film disposed on a rear surface of the cover panel and covering the through-hole,
wherein the release film comprises:
a first film including a front surface facing the cover panel; and
a second film which is disposed on the front surface of the first film, overlaps the through-hole and the cover panel on a plane, and has a higher light blocking property than the first film.

16. The display panel assembly of claim 15, wherein the release film further comprises an adhesive film disposed between the first film and the cover panel, and
at least a portion of the adhesive film is disposed between the first film and the second film.

17. The display panel assembly of claim 16, wherein the second film is in contact with the rear surface of the cover panel, and
on a cross section perpendicular to the rear surface of the cover panel, a length of a contact portion between the second film and the cover panel is about 0.5 mm or more.

18. The display panel assembly of claim 16, wherein the cover panel comprises a first cover portion in contact with the adhesive film and a second cover portion in contact with the second film, and
in a thickness direction of the cover panel, a first thickness of the first cover portion is greater than or equal to a second thickness of the second cover portion.

19. The display panel assembly of claim 15, wherein the first film is transparent, and
a color of the second film comprises a black color.

20. The display panel assembly of claim 15, wherein the release film further comprises a third film in contact with the front surface of the first film,
the first film comprises a first portion overlapping the cover panel on a plane and a second portion spaced apart from the cover panel on the plane,
the second film overlaps the first portion and is spaced apart from the second portion on the plane, and
the third film overlaps the second portion and is spaced apart from the first portion on the plane.
